(19) United States
(12) Patent Application Publication
(10) Pub. No.: US 2009/0267205 A1
(43) Pub. Date: Oct. 29, 2009

(54) Zero-reflow TSOP stacking

(75) Inventors: Paul M. Goodwin, Austin, TX (US); Ron Weindorf, Austin, TX (US)

Correspondence Address: Paul Goodwin, Suite 500, 9715A Burnet Road, Austin, TX, 78758, US

(73) Assignee: Avant Technology LP, Austin, TX (US)

(21) Appl. No.: 12/150,406

(22) Filed: Apr. 28, 2008

(51) Int. Cl. H01L 23/488

(52) U.S. Cl. 257/686; 257/E23.023

(57) ABSTRACT

The present invention mechanically integrates a flexible printed circuit pre-disposed with solder and flux and two or more leaded integrated circuit packages into an assembly that does not require a solder reflow process prior to the reflow cycle to attach the assembly to a printed circuit module. Each IC device includes: (1) a package having a top, a bottom and sides; and (2) external leads that extend out from one or more sides for electrical connectivity to a printed circuit module. Each flexible circuit includes: (1) a multi-segment pattern for each IC connection where there is a segment for: (a) attaching a package lead to the flexible printed circuit; (b) a segment for attaching a preformed piece of solder and flux; (c) a bridge for the solder to flow when heated to the package lead attach segment; (2) solder and flux and (3) adhesive to bond the flexible printed circuit to the packages and bond the packages together.

### TECHNICAL FIELD

The present invention relates to integrated circuit devices. More particularly, this invention relates to a flexible circuit interposer for a stacked integrated circuit module.

### BACKGROUND OF THE INVENTION

Designers of electronic component ranging from portable consumer electronics to massive computer platforms have constantly strived to reduce the size of the systems. The reasons vary from the convenience of carrying one's music library around in one's pocket to limiting the interconnect network in order to reduce the loading so that electrical signals may operate at higher speeds.

Various methods have been employed over the years to reduce the size of systems starting with integrating circuits onto a piece of silicon, then integrating multiple circuits into a single device. However, where multiple instances of a particular device was employed and the size of the die was at the point where no more could be integrated on the die, as is often the case with memory devices, the designers started stacking devices one atop another with an interconnect scheme that electrically connected common signals while isolating and re-routing unique signals.

The state of the art advanced and technologies were then developed that allowed the integration of multiple instances of the silicon die to be integrated into a single package. This provided the designers with components that had multiple instances of the silicon die in a single package without the need for an electrical and mechanical stacking. However, the trend to reduce the size of systems has outpaced the technology of integrating multiple die into a single package. The industry once again finds itself stacking like devices in a system.

A new requirement has been placed on electronic systems in recent years. Environmental concerns over the use of potentially hazardous substances in electronic systems have led to initiatives to eliminate the use of these substances. A key component in the solder that was used to electrically and mechanically connect semiconductor packages to modules and, of particular concern, stacks of devices together is lead (Pb).

While lead (Pb) in solder enabled low melting temperature solder. Lead free solders have much higher melting points. Typical lead-free solders require temperatures of up to 265° C. The silicon semiconductor devices do not fare well at high temperatures. Multiple cycles through reflow ovens at lead-free reflow temperatures are having an adverse effect on the semiconductor devices. Some of the failures due to lead-free solder reflow cycles are data retention (memory devices), bond wire corrosion and hard failures of the devices. This has caused the manufactures of the semiconductors to specify a maximum number of reflow cycles that the devices experience.

Many stacking technologies used today require multiple reflow cycles to assemble the stacked module. In some cases the number of reflow cycles may exceed the specified maximum for the devices that are being stacked. Then the stacked assemblies have to be attached to modules where they could experience two or more reflow cycles.

Accordingly, what is needed is an improved apparatus for electrically and mechanically coupling stacked integrated circuit devices that reduces or eliminates high-temperature reflow cycles from the stack assembly process.

### SUMMARY OF THE INVENTION

The present invention aggregates multiple leaded package devices into stacked module subassemblies without the need for reflow cycles to electrically and mechanically bond the devices together prior to being assembled onto PCB. When the stacked module is placed on the module and run through the reflow oven pre-dispensed solder and flux in the stack bond the leads together at the same time that the stacked module subassembly is being soldered to the module.

The present invention increases the capacity of the device footprint, minimizes the interconnection network length, and provides ample power to all devices without the need of high temperature reflow cycles in the assembly process. The present invention can be used advantageously to increase the total memory capacity of portable consumer electronics or a computing system.

In a preferred embodiment implemented in accordance with the present invention a flexible printed circuit approximately equal to the length of the side of the semiconductor package to be stacked where electrical leads are disposed is patterned on a first side with an electrically conductive material to align with the foot of the leads of an upper device. The flexible printed circuit is patterned on the second side an electrically conductive material to align with the shoulders of the leads of the lower device in the stack. These patterns have a one to one correspondence with the leads of the packages to be stacked. The electrically conductive pattern on the flexible printed circuit is divided into three segments. The first segment is the area that comes into contact with the lead of the package being stacked and its size is in accordance with good surface mount practices. The second segment is located adjacent to the first segment and is connected to the first segment by a third segment. The second segment is sized to have a preformed piece of solder and flux attached of sufficient size that when heated will flow across the third section coating the first section and a sufficient portion of The features and advantages of the invention will become apparent upon reading the following specification, when taken in conjunction with the accompanying drawings.

### BRIEF DESCRIPTION OF THE DRAWINGS

FIG. 1 depicts the present invention.

FIG. 2 shows lead bearing edge view of present invention.

FIG. 3 shows non-lead bearing edge view of present invention.

FIG. 4 depicts flexible circuit interposer.

FIG. 5 depicts the types of contact pads used on interposer module

FIG. 6 depicts the interposer sub assembly

FIG. 7 Depicts a cross section of the flex circuit through the footprint and solder reservoir.

FIG. 8 shows the process flow for creating the interposer sub-assembly.

FIG. 9 shows an exploded view in cross section of a contact bearing edge of the present invention.

FIG. 10 shows the interposer subassembly mounted on the lower device in cross section of a contact bearing edge of the present invention.

FIG. 11 shows in cross section of a contact bearing edge the present invention the assembled stack.

FIG. 12 shows in cross section of a contact bearing edge the present invention placed on a module prior to the solder reflow cycle.

FIG. 13 shows in cross section of a contact bearing edge the present invention placed on a module after the solder reflow cycle.

FIG. 14 depicts an alternative embodiment of the present invention mounted on a module

FIG. 15 shows an exploded view in cross section of a contact bearing edge of an alternative embodiment of present invention.

FIG. 16 shows in cross section of a contact bearing edge an alternative embodiment of present invention.

FIG. 17 shows in cross section of a contact bearing edge an alternative embodiment of the present invention placed on a module after the solder reflow cycle

FIG. 18 depicts the process flow for creating the present invention.

FIG. 19 depicts the process flow for creating an alternative embodiment of the present invention.

FIG. 20 shows an exploded view in cross section of a contact bearing edge of yet another alternative embodiment of present invention.

### DESCRIPTION OF PREFERRED EMBODIMENT

The following embodiments introduce new construction concepts directed at providing higher-density memory solutions with fewer solder re-flow cycles leading to a higher reliability module. The embodiments disclosed herein may be broadly classified as “Multi-Chip Modules” in that they are comprised of multiple packages in a vertical stack.

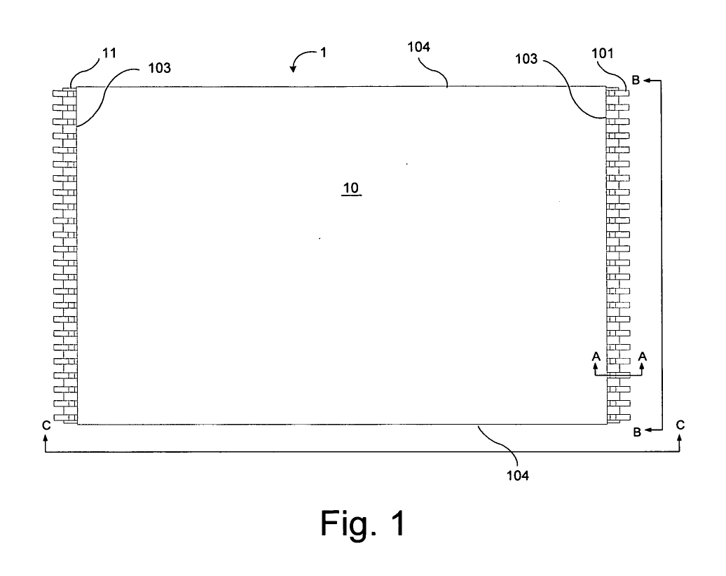

FIG. 1 depicts a top view of the stacked module 1 of the present invention. Visible is a device 10 that is known in the industry as a Thin Small Outline Package (TSOP) type-1. Semiconductors that are available in this package are typically flash devices. One skilled in the art will appreciate that the present invention may be employed to stack any leaded package.

The upper device 10 is the only device 10 visible in this view because the lower device 10 is placed directly below the upper device 10. The flexible interposer assembly 11 is visible where it protrudes beyond the extent of the lead bearing edge 103 of the device 10.

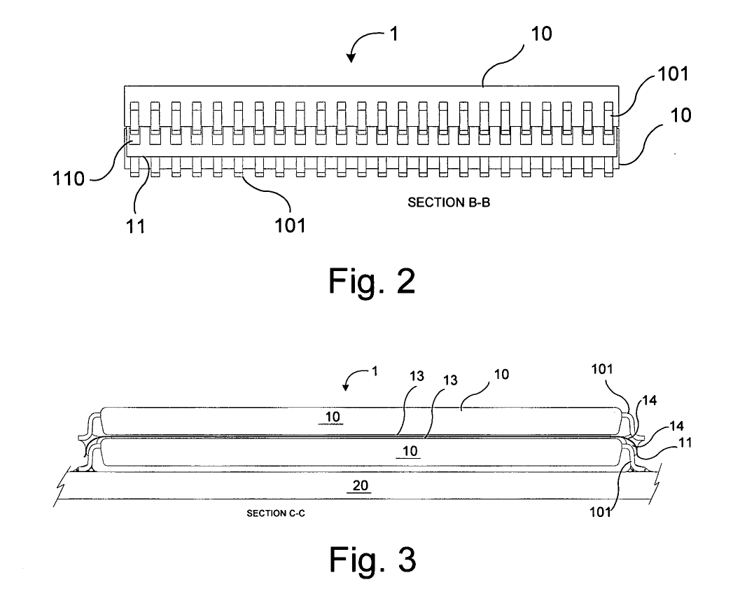

FIG. 2, view B-B of FIG. 1, is an elevation of the lead 101 bearing side 103 of the stacked module 1. Here it starts to be come clear how the stacked module 1 interconnects the upper and lower devices 10. The leads 101 of the upper device 10 are aligned over contacts 110 on the interposer sub-assembly 11. The interposer subassembly 11 had previously been positioned over the lower device 10 with the contacts 110 aligned with the leads 101.

While the preferred embodiment is to stack two of the same package types one skilled in the art will be appreciated how the present invention may be used to stack different package types.

FIG. 3, view C-C of FIG. 1, is an elevation of the non-lead bearing side 104 of the stacked module 1 mounted to a Module 20. In this view the connection of the lead 101 of the lower device 10 is connected to the flexible circuit interposer 11 with solder 14 and the lead 101 of the upper device 10 is connected to the interposer through solder 14. Additionally the lower device 10 is bonded to the interposer subassembly 11 with an adhesive 13 and the upper device 10 is bonded to the interposer subassembly 11 with a second layer of adhesive 13.

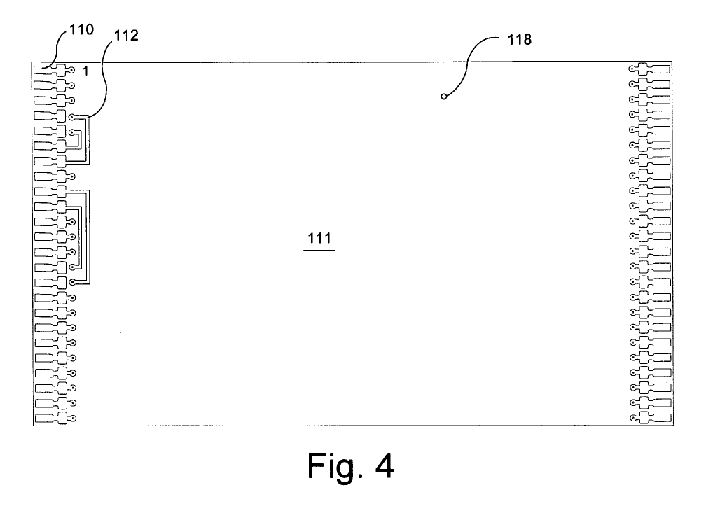

FIG. 4 shows the flexible circuit module 111 that is used to create the interposer 11 sub-assembly. Shown is a flexible circuit 111 with a top surface 118 that is bonded to an upper device 10 and a bottom surface 119 that is bonded to the lower device 10. Disposed along the edges of the flexible circuit 111 are rows of contacts 110 that align with the leads 101 of the devices 10 to be stacked. In addition to the contacts there may be etch that connects the contact pad 110 with a via to route to a circuit on the other side of the module, or to another pad on the current side of the flex circuit.

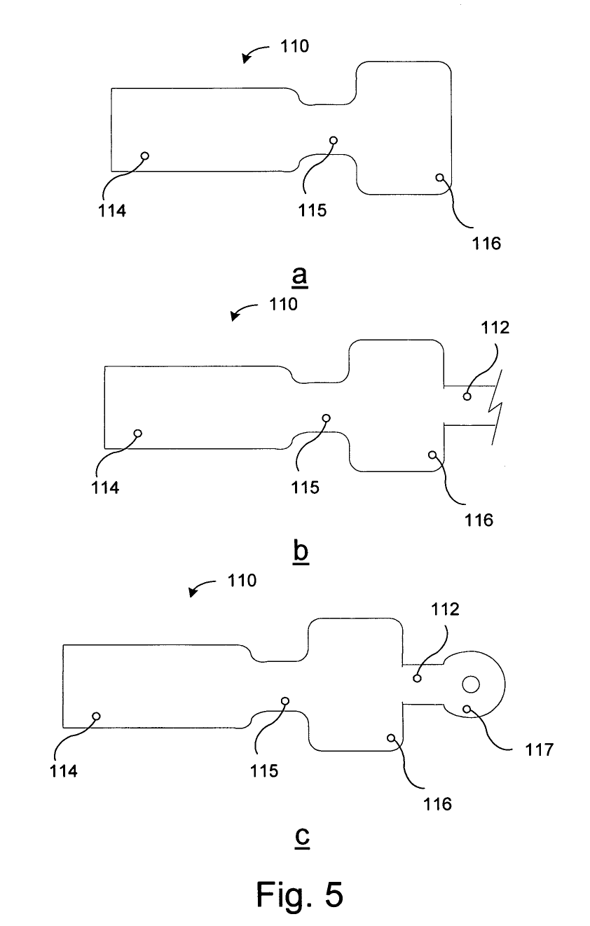

FIG. 5a details the contact pad 110 that is a key part of the stacked module 1. The contact pad 110 is divided into three separate sections. First is the contact region 114. The contact region 114 is the area where the bond to the device 10 lead 110 is made. The second region 116 is a reservoir region where a solder and flux composite is attached prior to assembling the stack. The third region is a bridge 115 between the contact region 114 and the reservoir region 116. In an alternative embodiment the solder flux composite may be replaced with a solder ball and a flux applied separately.

The reservoir region is positioned such that when the stacked module 1 is heated in a solder reflow oven capillary action and gravity will draw the molten solder and flux across the bridge 115 to form an electrical and mechanical bond between the contact region 114 and the device lead 101.

The contact may have additional features as shown in FIG. 5b and FIG. 5c. In FIG. 5b a piece of etch 112 extends from the reservoir region 116 to connect to another feature on the flexible circuit module 111. FIG. 5b shows a typical implementation of the contact 110 where a short run of etch 112 connects the reservoir to a pad w/via 117. This arrangement is typically used with an identical contact 110 on the opposite side of the flexible circuit 111. In this configuration the contacts 110 on the top side 118 and the bottom side 119 of the flexible circuit 111 are electrically connected through the via 117. Another application of this configuration of FIG. 5c is where this configuration is used on the bottom side 119 and the via connects to etch 112 on the top side 118 that re-routs the signal brought into the stacked module 1 on a lead 101 on the lower device and used by the upper device 10 on a different lead 101.

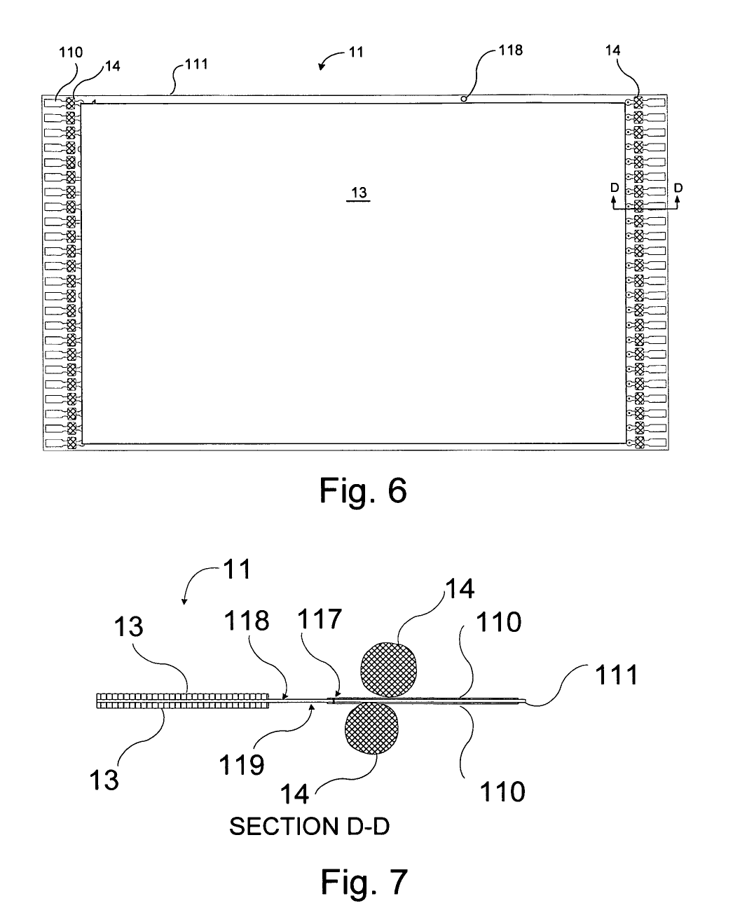

The completed interposer sub-assembly 11 is shown in FIG. 6. Disposed on the reservoir region 116 of the contact pad 110 is a preformed piece of solder-flux composite 14. On the region of the flexible circuit that is sandwiched between the two packages to be stacked one or more pieces of adhesive 113 are placed. The adhesive 13 on the bottom side 119 bonds the lower device 10 to the interposer sub-assembly 11 and the adhesive 13 on the upper side 118 bonds the upper device 10 to the interposer subassembly 11 thus bonding the upper device 10 to the lower device 10 until the stacked module 1 is placed on a module and the solder-flux composite 14 bonds the leads 101 together during a solder re-flow procedure.

FIG. 7 shows the cross section view D-D from FIG. 6. Here the placement of contacts 110 opposite each other on the top side 118 and the bottom side 119 of flex circuit 111. The via 117 electrically connects the contacts 110. On the reservoir region 116 the solder-flux composite 14 is attached.

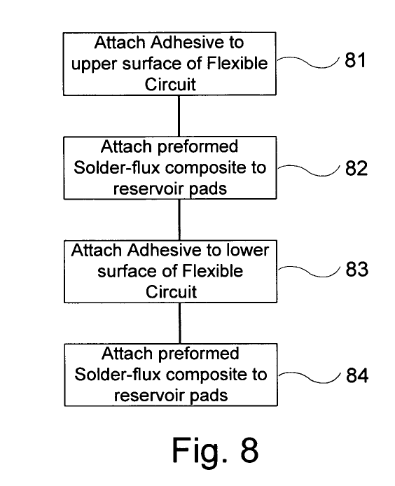

FIG. 8 presents a sequence of process steps used to assemble the interposer 11. In process step 81 The bare flexible printed circuit 111 has an adhesive disposed on side 118 and in Process step 82 the preformed solder and flux composite 14 are attached to the reservoir region 116 of the contacts 110. Then in step 83 the flexible circuit is flipped over and an adhesive is disposed on site 119 and the preformed solder and flux composite 14 are attached to the reservoir region 116 of the contacts 110. The interposer subassembly 11 is now ready to assemble the stacked module 1.

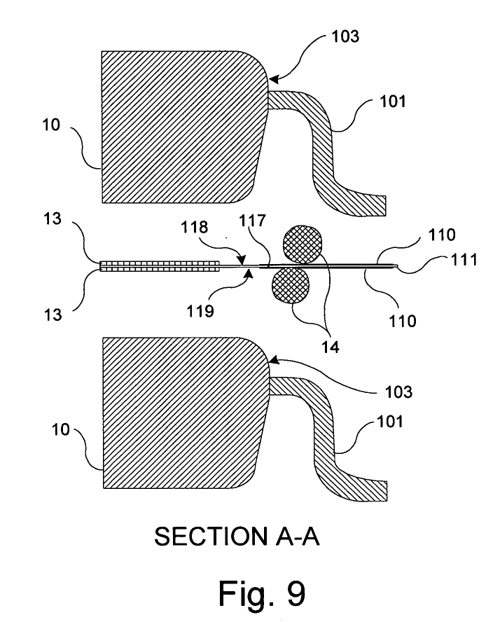

FIG. 9 is an exploded view of the stacked module 1 through the cross section A-A from FIG. 1. There are upper and lower devices 10 with leads 101 protruding from a lead bearing edge 103. The leads 101 from the upper and lower devices 10 align with contact pads 110 in the flexible circuit 111. Attached to the contact 110 is a preformed piece of a solder-flux composite 14.

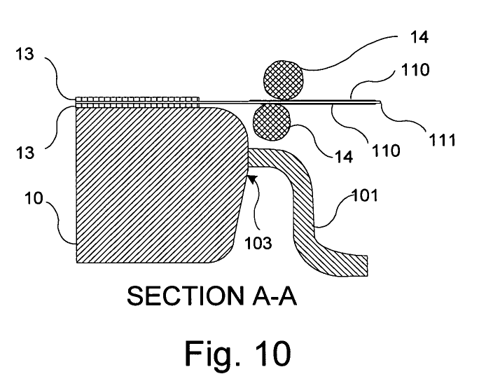

FIG. 10 shows the step 82 in creating the stacked module 1. The contact 110 has been aligned with the lead 101 and the adhesive 13 has bonded the interposer 11 to the lower device 10. The preformed solder-flux piece 14 may or may not contact the lead 101 at this point depending on where on the lead bearing edge 103 the lead 101 protrudes.

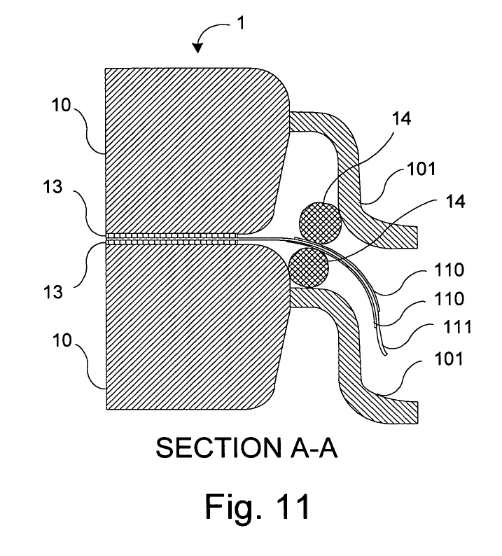

FIG. 11 shows the completed stacked assembly. The upper device 10 has been positioned over the lower device 10 and Interposer 11 sub-assembly from FIG. 10. At this point the stacked assembly has not been subjected to a solder reflow cycle. The preformed solder-flux composite 14 is still in the preformed state.

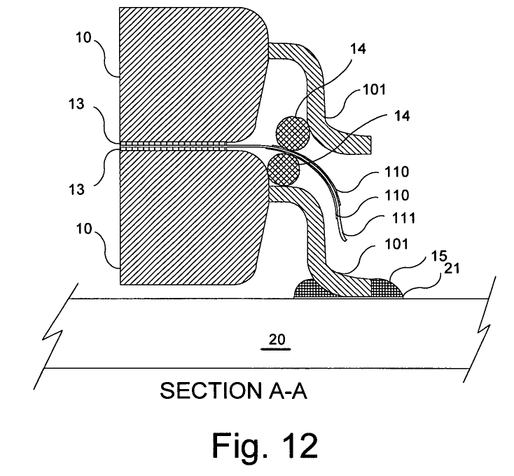

FIG. 12 shows the stacked assembly 1 of FIG. 11 placed on a PCB 20. The leads 101 of the lower device 10 are used to electrically and mechanically bond the stacked module 1 to the module 20. This is done by aligning the leads 101 of the lower device 10 with the pads 21 on the module 20. Disposed on the pad 21 prior to placing the stacked module 1 is a solder paste 15.

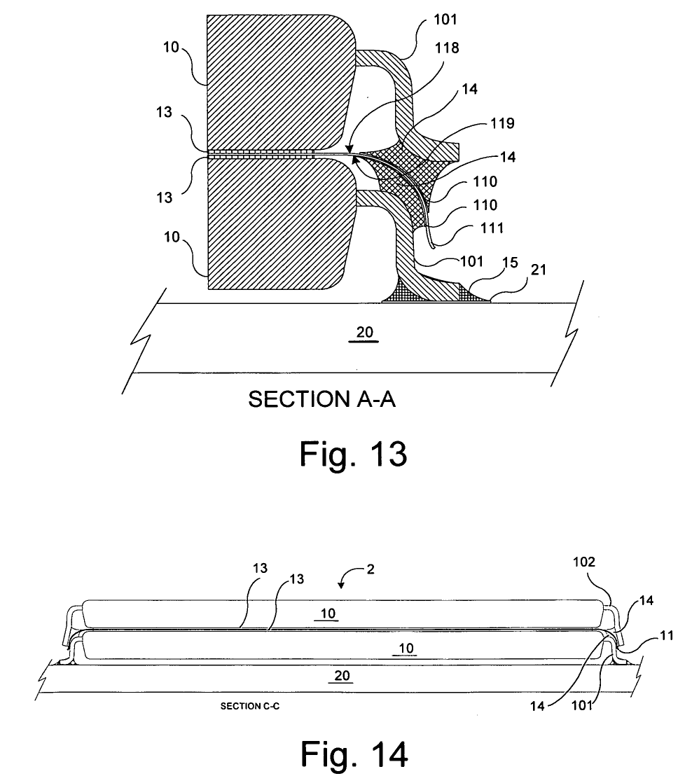

FIG. 13 shows a view of the stacked module 1 through the cross section A-A from FIG. 1 after the solder reflow process. The solder paste 15 has melted and bonded to the lead 101 of the lower device 10 to the pad 21 of the module 20. The pre-formed solder flux composite 14 attached to the bottom side 119 of the interposer 11 has melted and flowed from the reservoir 116 across the bridge 115 and bonded the lead 10 to the contact pad 114. The pre-formed solder flux composite 14 attached to the top side 118 of the interposer 11 has melted and flowed from the reservoir 116 across the bridge 115 and bonded the lead 10 to the contact pad 114.

FIG. 14 shows an alternative embodiment of the present invention In this embodiment the leads 102 of the upper device 10 have been re-shaped prior to being placed in the stacked assembly 2.

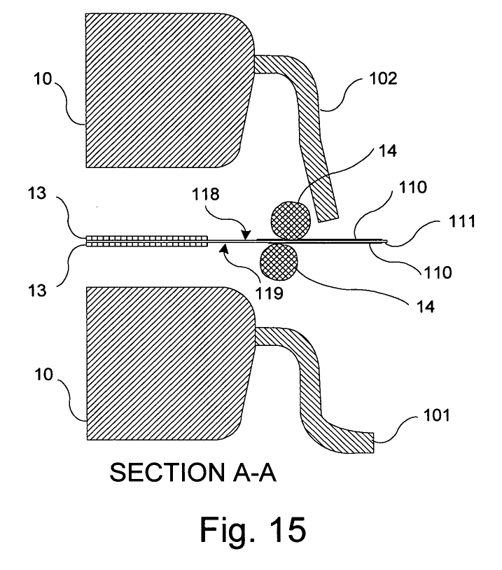

FIG. 15 is an exploded view of the alternative embodiment of the stacked module 2 through the cross section A-A from FIG. 1. The leads 101 from the lower device 10 protruding from a lead bearing edge 103 are un-modified. The leads 102 from the upper device 10 protruding from a lead bearing edge 103 are straightened.

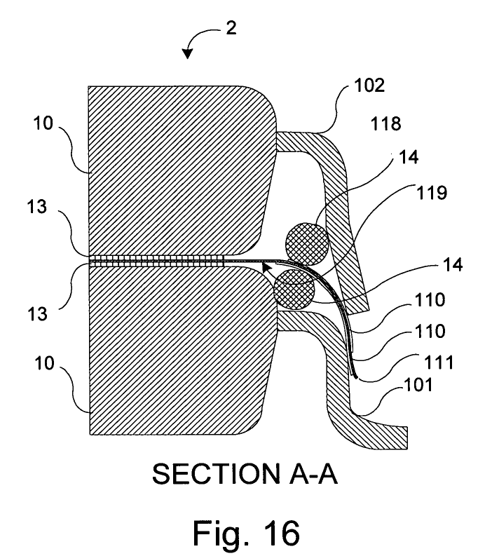

FIG. 16 shows the completed alternative embodiment of the present stacked module 2. The upper device 10 has been positioned over the lower device 10 and Interposer 11 sub-assembly from FIG. 10. The re-shaped lead 102 of the upper device 10 has deflected the interposer 11 so that the contact 110 on the bottom side 119 of interposer 11 has come into contact with the lead 101 from the lower device 10 and the contact 110 on the upper surface 118 and come into contact with the lead 102 of the upper device 10.

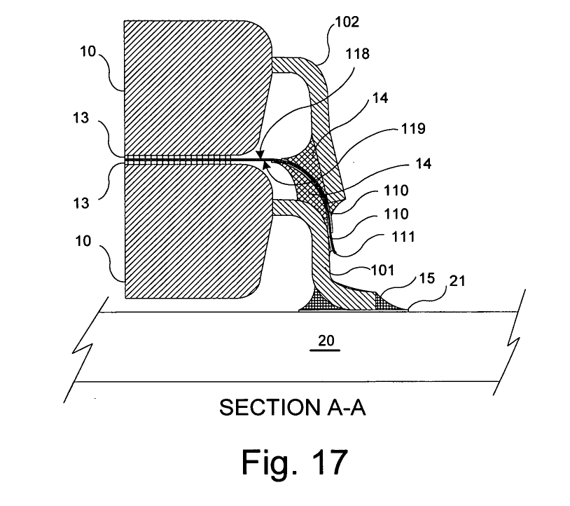

FIG. 17 shows a view of alternative embodiment of the stacked module 2 through the cross section A-A from FIG. 1 after the solder reflow process to mount the assembly 2 to the module 20. The solder paste 15 has melted and bonded to the lead 101 of the lower device 10 to the pad 21 of the module 20. The pre-formed solder flux composite 14 attached to the bottom side 119 of the interposer 11 has melted and flowed from the reservoir 116 across the bridge 115 and bonded the lead 101 to the contact pad 114. The pre-formed solder flux composite 14 attached to the top side 118 of the interposer 11 has melted and flowed from the reservoir 116 across the bridge 115 and bonded the lead 102 to the contact pad 114.

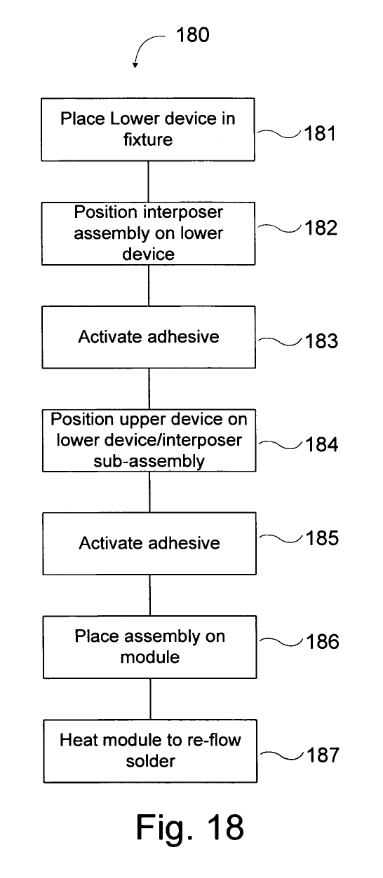

FIG. 18 presents a sequence of process steps used to assemble the stacked module 1. The lower device 10 is placed in a fixture or on a surface in step 181 to support it during the assembly process. In the next process step 182 the interposer subassembly 11 is placed on the lower device from the previous step 181. FIG. 10 depicts the result of this step 182. In the next step 183 the adhesive 13 bonding the interposer subassembly 11 to the lower device 10 is activated. The adhesive may be a pressure sensitive adhesive (PSA) where the placement of the interposer subassembly 11 on the lower device 10 will activate the adhesive or it may be a thermal set adhesive such as 3M's APAS where a relatively small rise in temperature will partially set the adhesive.

The next step 184 is to place the upper device 10 on the lower device 10 and interposer subassembly 11. As in the previous adhesive activation step 183 the adhesive 13 bonding the upper device 10 to the interposer subassembly 11 is activated.

With the devices 10 stacked and mechanically bonded together into the stacked module 1 the assembly is placed on a module 20 that has had solder paste 15 disposed on the surface mount pads 21 in the next step 186. The module 20 and stacked module 1 are then subjected to temperatures sufficient to melt the solder paste (15) and the solder and flux composite (14) in the present invention.

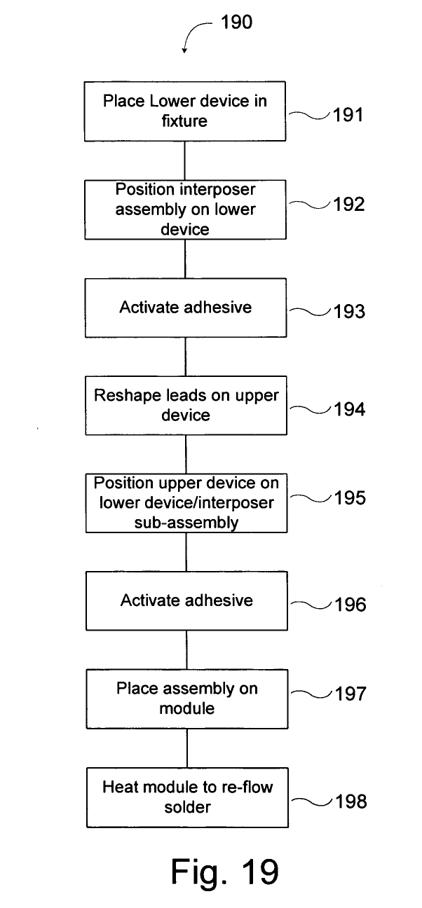

The process shown in FIG. 19 is the same as the process of FIG. 18 with the addition of an intermediate step 194 to reshape the leads 101 of the upper device 10. This process flow shows the reshape step 194 prior to the device 10 being placed on the device 10 and interposer subassembly 11. One skilled in the art can appreciate that this step 194 could also be done after the upper device 10 is placed on the lower device 10 and interposer subassembly 11.

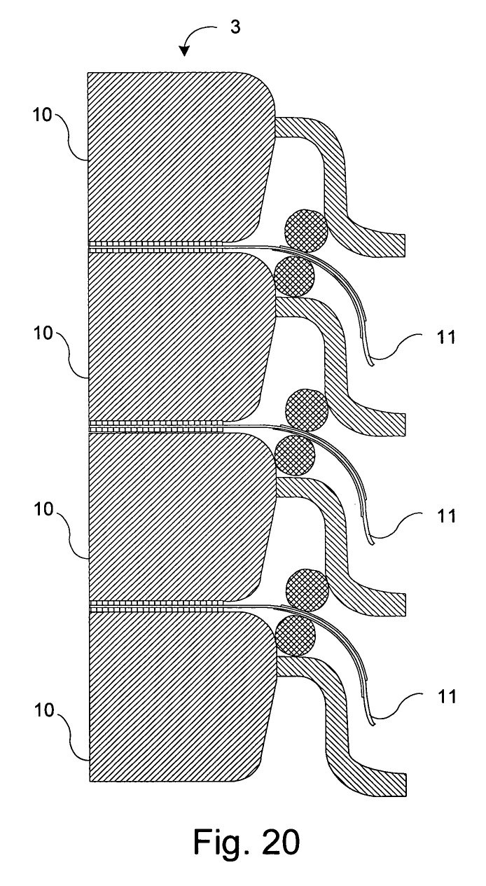

FIG. 20 depicts yet another embodiment of the stacked module 3. Here multiple devices 10 are stacked with an interposer 11 between each device 10.

It will be seen by those skilled in the art that various changes may be made without departing from the spirit and scope of the invention. For example, while the stacked module 1 has primarily been described in terms of a first and a second IC device, skilled persons will recognize that a stacked module 1 of the present invention may include multiple stacked IC devices coupled together by flexible circuit conductors mounted between adjacent devices.

Furthermore, in the depicted embodiment, Thin Small Outline Packaged (TSOP) devices with leads extending from one pair of oppositely-facing peripheral sides are shown. However, the invention can be used with any commercially available packaged devices and other devices including but not limited to TSOP, custom thin, and high lead count packaged integrated circuit devices.

Accordingly, the present invention is not limited to that which is expressly shown in the drawings and described in the specification.

What is claimed is:

1. A stacked IC module that does not require solder reflow operations during assembly comprising:
(a) first and second IC packages, each of the first and second IC packages comprising: (1) top, bottom, and peripheral sides; and (2) external leads that extend from one or more of the peripheral sides;
(b) a flexible printed circuit interposer having a first side and a second side disposed between said first and second packages;
(c) said flexible printed circuit interposer including discrete surface mount features disposed on said first and second sides comprising: (1) a region for attaching a lead from said first or second package; (2) a region for a reservoir of solder and flux; and a segment connecting the first and second segments for the solder and flux to flow to the lead segment from the reservoir segment when heated to the reflow temperature of the solder; and interconnect network connecting selected surface mount features;
(d) said contacts disposed along an edge of said flexible printed circuit interposer that corresponds with said edge bearing peripheral edge;
(e) said flexible printed circuit interposer to be of sufficient length and width such that said contact bearing edges extend beyond the package so said contacts align with the leads of said package;
(f) an adhesive on said first side and said second side of said interposer; and
(g) pre-formed pieces of a solder and flux composite attached to the reservoir segment of the surface mount feature.

2. The stacked IC module of claim 1 in which the adhesive is a thermal set adhesive.

3. The stacked IC module of claim 1 in which the adhesive is a pressure sensitive adhesive.

4. The stacked IC module of claim 1 in which the devices have leads extending from two peripheral sides

5. The stacked IC module of claim 1 in which the devices are type 1 thin small outline packages (TSOP).

6. The stacked IC module of claim 1 in which the devices are flash memory.

7. The stacked IC module of claim 1 in which the devices are type 2 thin small outline packages (TSOP).

8. The stacked IC module of claim 1 in which the devices are DRAM memory.

9. The stacked IC module of claim 1 in which the said lower device is the IC stack of claim 1 and said upper device is the IC stack of claim 1.

10. The stacked IC module of claim 1 in which the devices have leads extending from four peripheral sides

11. A stacked IC module that does not require solder reflow operations during assembly comprising:
(a) first and second IC packages, each of the first and second IC packages comprising: (1) top, bottom, and peripheral sides; and (2) external leads that extend from one or more of the peripheral sides;
(b) a flexible printed circuit interposer having a first side and a second side disposed between said first and second packages;
(c) said flexible printed circuit interposer including discrete surface mount features disposed on said first and second sides comprising: (1) a region for attaching a lead from said first or second package; (2) a region for a placement of a solder ball; and a segment connecting the first and second regions for the solder to flow to the lead segment from the reservoir segment when heated to the reflow temperature of the solder; and interconnect network connecting selected surface mount features;
(d) said contacts disposed along an edge of said flexible printed circuit interposer that corresponds with said edge bearing peripheral edge;
(e) said flexible printed circuit interposer to be of sufficient length and width such that said contact bearing edges extend beyond the package so said contacts align with the leads of said package;
(f) an adhesive on said first side and said second side of said interposer;
(g) solder balls attached to the reservoir region of the surface mount feature; and
(h) a solder flux compound applied to said solder balls and said contact region of surface mount feature.

12. The stacked IC module of claim 11 in which the adhesive is a thermal set adhesive.

13. The stacked IC module of claim 11 in which the adhesive is a pressure sensitive adhesive.

14. The stacked IC module of claim 11 in which the devices have leads extending from two peripheral sides

15. The stacked IC module of claim 11 in which the devices are type 1 thin small outline packages (TSOP).

16. The stacked IC module of claim 11 in which the devices are flash memory.

17. The stacked IC module of claim 11 in which the devices are type 2 thin small outline packages (TSOP).

18. The stacked IC module of claim 11 in which the devices are DRAM memory.

19. The stacked IC module of claim 11 in which the said lower device is the IC stack of claim 11 and said upper device is the IC stack of claim 11.

20. The stacked IC module of claim 11 in which the devices have leads extending from four peripheral sides
